(19) United States
(12) Patent Application Publication
(10) Pub. No.: US 2009/0027865 A1
(43) Pub. Date: Jan. 29, 2009

(54) Surface Mount Electrical Component

(76) Inventor: Junya Tsuji, Tokyo (JP)

Correspondence Address: BARLEY SNYDER, LLC, 1000 WESTLAKES DRIVE, SUITE 275, BERWYN, PA, 19312, US

(21) Appl. No.: 11/815,539

(22) PCT Filed: Jan. 6, 2006
(86) PCT No.: PCT/JP2006/300317

§ 371 Date: Aug. 3, 2007

(30) Foreign Application Priority Data
Feb. 4, 2005 (JP) 2005-028995

(51) Int. Cl. H01R 9/00; H05K 3/34

(52) U.S. Cl. 361/772; 29/840

(57) ABSTRACT

A surface mount electrical component comprising a first soldering interface having a fist soldering interface total solder path length of sufficient length such that a first melted solder fillet substantially disposed along the first soldering interface total solder path length produces an first upward moment greater than a first downward moment produced by the weight of the surface mount electrical component about the first soldering interface, and a second soldering interface comprising a second soldering interface total solder path length such that a surface tension produced by a second melted solder fillet substantially disposed along the second soldering interface total solder path length produces a second upward moment greater than a second downward moment produced by the weight of the surface mount electrical component about the second soldering interface is disclosed.

### CROSS-REFERENCE TO RELATED APPLICATION DATA

This application claims the benefit of the earlier filed parent international application number PCT/JP2006/300317 having an international filing date of Jan. 6, 2006 that claims the benefit of JP2005-028995 having a filing date of Feb. 4, 2005.

### FIELD OF THE INVENTION

The present invention relates to a surface mount electrical component, and more specifically, to a surface mount electrical component configured to have sufficient solder surface tension to prevent falling from an underside of a substrate during a reflow soldering process.

### BACKGROUND

Various types of surface mount electrical components are known. It is also generally known that the surface mount electrical components may be surface mounted on both sides of a printed circuit board or substrate. When the surface mounting is performed on both sides of a substrate, initially (in first soldering), electrical/electronic components to be mounted on one side of the substrate are soldered by reflow soldering, then (in second soldering), the substrate is inverted and other electrical/electronic components are surface mounted by a subsequent reflow soldering. A problem here is that the solder at the portions of the components initially soldered on the substrate are melted during the second reflow soldering, and some of the electrical/electronic components initially attached to the substrate are likely to fall off the substrate due to their own weight.

Various methods have attempted to address this problem. For example, Japanese Unexamined Patent Publication No. 2001-358456 proposes a method in which the environmental temperature of the reflow soldering, i.e. melting range of the solder, is different between the first and second times, so that the solder portions initially soldered and located on the underside of the substrate are not melted.

Another method, in which soldering is performed after electrical/electronic components (packages) are temporarily bonded to the substrate using an adhesive, is also known as described, for example, in Japanese Unexamined Patent Publication No. 10(1998)-256433 (FIG. 5). This prevents the packages on the underside of the substrate from falling off when the substrate is inverted and reflow soldering is performed.

Further, in order to prevent a connector on the underside of a substrate from falling off the substrate, a configuration in which a solder peg is additionally provided as a stabilization compensation member on the side of the connector which is more likely to be separated from the board by the rotational moment is known as described, for example, in Japanese Unexamined Patent Publication No. 2003-115334 (FIG. 4). Still further, as a method for enhancing the soldering strength of such a solder peg, it is known that a through hole is created in the solder peg to broaden the area of a solder fillet as described, for example, in Japanese Unexamined Patent Publication No. 10 (1998)-064608 (FIG. 1).

The method in which the solder melting temperature is different as disclosed in Japanese Unexamined Patent Publication No. 2001-358456, however, requires two types of reflow furnaces accommodating different melting temperatures, which poses a problem of high costs for equipment investment and maintenance. Further, the package disclosed in Japanese Unexamined Patent Publication No. 10 (1998)-256433, which is temporarily attached to a substrate by applying an adhesive to a protrusion provided on the underside of the package facing the substrate, requires the adhesive, as well as equipment and process (manpower) for applying the adhesive with a dispenser and solidifying the adhesive in a hardening furnace.

As disclosed in Japanese Unexamined Patent Publication Nos. 2003-115334 and 10 (1998)-064608, the soldering strength may be increased by adding a solder peg, and creating a hole in the solder peg to increase the area (area or line length) of a solder fillet. However, when the soldered portion of a component is melted by the second reflow soldering, the component is not always securely retained due to the relationship between the surface tension of the soldered portion and rotational moment of the weight centered at the center of gravity. That is, the surface tension required of the soldered portion differs depending on the location of the center of gravity, and location and size of the fillet. Accordingly, there may be cases where retaining power of the surface tension is insufficient even when a solder peg is additionally provided.

The present invention has been developed in view of the circumstances described above, and it is an object of the present invention to provide a surface mount electrical component which is less likely to fall off a substrate when placed on the underside of the substrate by inverting the substrate and subjected to a second reflow in an ordinary soldering process, without requiring investment for additional soldering equipment.

### SUMMARY

The present invention relates to a surface mount electrical component comprising a first soldering interface having a fist soldering interface total solder path length of sufficient length such that a first melted solder fillet substantially disposed along the first soldering interface total solder path length produces an first upward moment greater than a first downward moment produced by the weight of the surface mount electrical component about the first soldering interface, and a second soldering interface comprising a second soldering interface total solder path length such that a surface tension produced by a second melted solder fillet substantially disposed along the second soldering interface total solder path length produces a second upward moment greater than a second downward moment produced by the weight of the surface mount electrical component about the second soldering interface.

### BRIEF DESCRIPTION OF THE DRAWINGS

FIG. 1A is a front view of a surface mount electrical component according to an embodiment of the present invention, illustrating an overview thereof;

FIG. 1B is a plan view of the surface mount electrical component shown in FIG. 1A;

FIG. 1C is a rear view of the surface mount electrical component shown in FIG. 1A;

FIG. 2A is a bottom view of the surface mount electrical component shown in FIG. 1A;

FIG. 2B is a left side view of the surface mount electrical component shown in FIG. 1A;

FIG. 2C is a right side view of the surface mount electrical component shown in FIG. 1A;

FIG. 3 is a partially enlarged cross-sectional view taken along the line 3-3 in FIG. 1B;

FIG. 4 is an enlarged plan view of an electrical contact with a carrier strip;

FIG. 5A is a side view of the electrical contact separated from the carrier strip;

FIG. 5B is a bottom view of the electrical contact separated from the carrier strip;

FIG. 6 is a schematic diagram illustrating a state in which a substrate with a surface mount electrical component, surface mounted thereon, is inverted for a second reflow soldering;

FIG. 7 is a schematic diagram illustrating a rectangular soldering portion as a specific shape of a fixing portion of a surface mount electrical component; and

FIG. 8 is a schematic diagram illustrating a soldering portion having another shape.

### DETAILED DESCRIPTION OF THE EMBODIMENT(S)

Note that the surface mount electrical component comprises electronic components, such as semiconductor chips, packages having an outer lead and the like, as well as electrical components such as electrical connectors and the like.

The term “overall-heating soldering” as used herein means a method in contrast to “partial-heating soldering” using a soldering iron, pulse heater, hot air, or flow, and comprises reflow soldering.

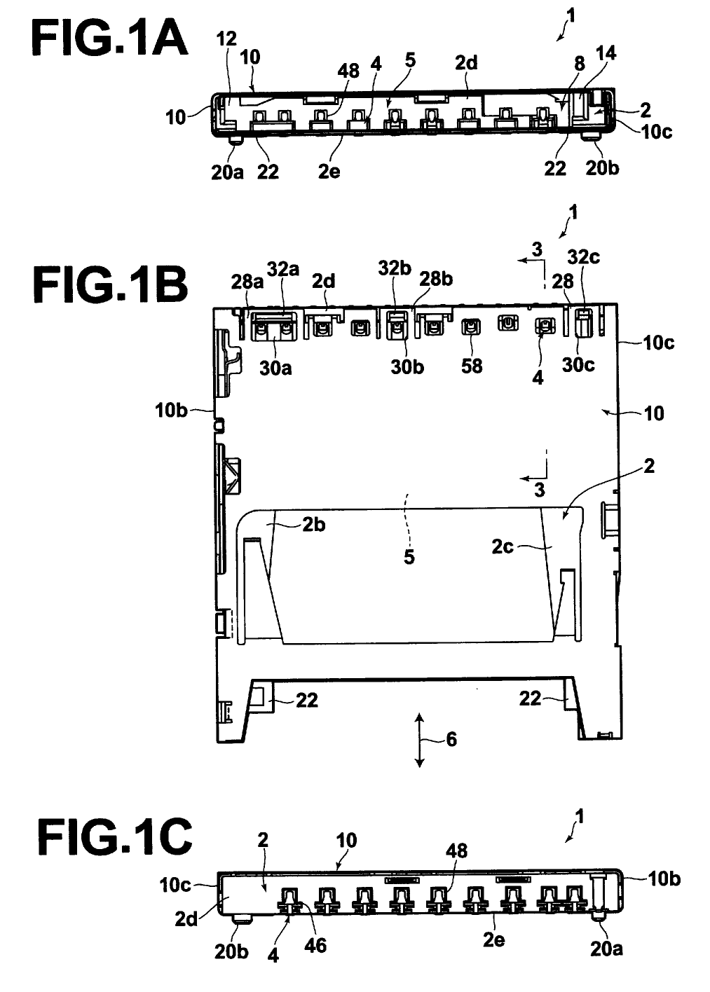

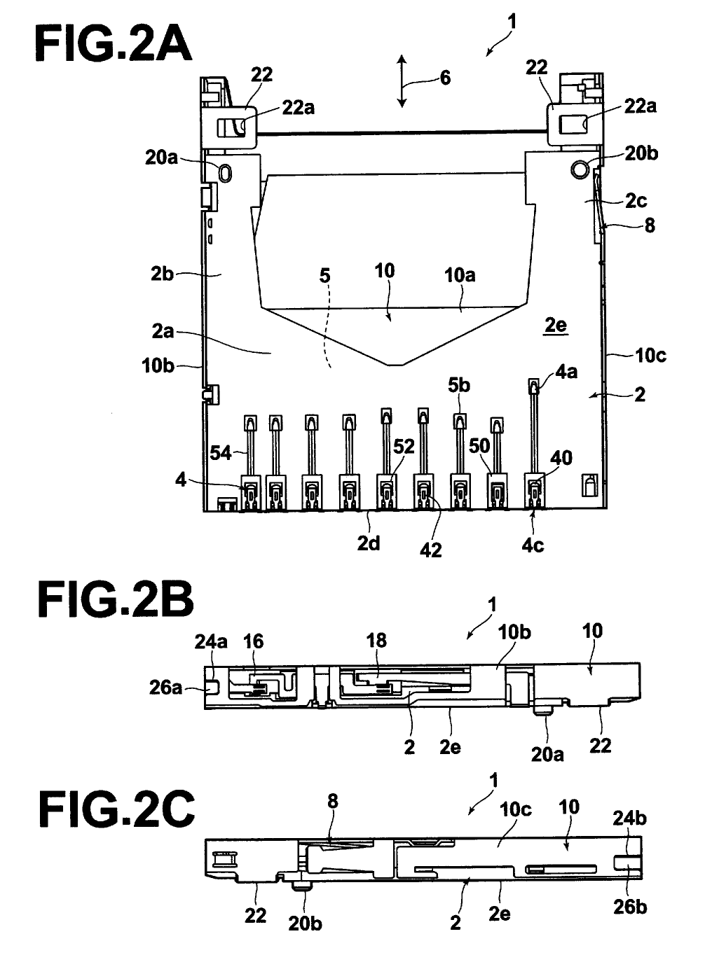

Hereinafter, an exemplary embodiment of a surface mount electrical connector (hereinafter, simply referred to as “connector”), which is an example electrical component of the present invention, will be described with reference to the accompanying drawings. First, an overview of the connector 1 will be described with reference to FIGS. 1A to 2C. In the following description, the term “front” means a side from where a card (not shown) is inserted (downside in FIG. 1B), and “rear” means a side opposite to the front in the plan view of the connector 1 in FIG. 1B. The connector 1 is a card connector and comprises a housing 2, contacts 4 held by the housing 2, an ejection mechanism 8, and a metal shell 10 attached to the housing and substantially covering these components. The ejection mechanism 8 is a mechanism that moves along card insertion-removal directions 6 (FIGS. 1B, 2A) according to insertion/removal of a card.

The housing 2 comprises a body 2a located in the rear portion thereof, and first and second card guides 2b, 2c extending from the body 2a to the front side. The body 2a is open on the upper side and comprises a body rear wall 2d at the rear end. The first and second card guides 2b, 2c comprise first and second card guide paths 12, 14 respectively, on the inner side thereof (FIG. 1A). The card guide paths 12, 14 extend to the inside of the body 2a. The card guide 2b comprises first and second detection contacts 16, 18 (FIG. 2B) for detecting insertion of a card or readiness of the card for write operation, but these are not the subject matter of the present invention and will not be described in detail here. The housing bottom surface 2e of the housing 2 is substantially flat, but comprises first and second positioning bosses 20a and 20b at the front ends of the card guides 2b, 2c respectively.

The second card guide 2c comprises an ejection mechanism 8 which is formed such that when a card is inserted into the connector 1 from the front side and pushed into the inside of the connector 1, the card is held at the position inside the connector 1, and when the card is pushed again, it is ejected from the connector 1. The ejection mechanism 8 comprises a slider (not shown) which operates by an insertion/ejection operation. The slider is constantly urged by a spring toward the front side of the housing. The ejection mechanism 8 comprises a heart-shaped cam groove (not shown) like that as disclosed in Japanese Unexamined Patent Publication No. 2004-207168, and a cam follower (not shown) that moves within the cam groove. This structure is well known in the art, and in addition, it is not the subject matter of the present invention, so that it will not be described in detail here.

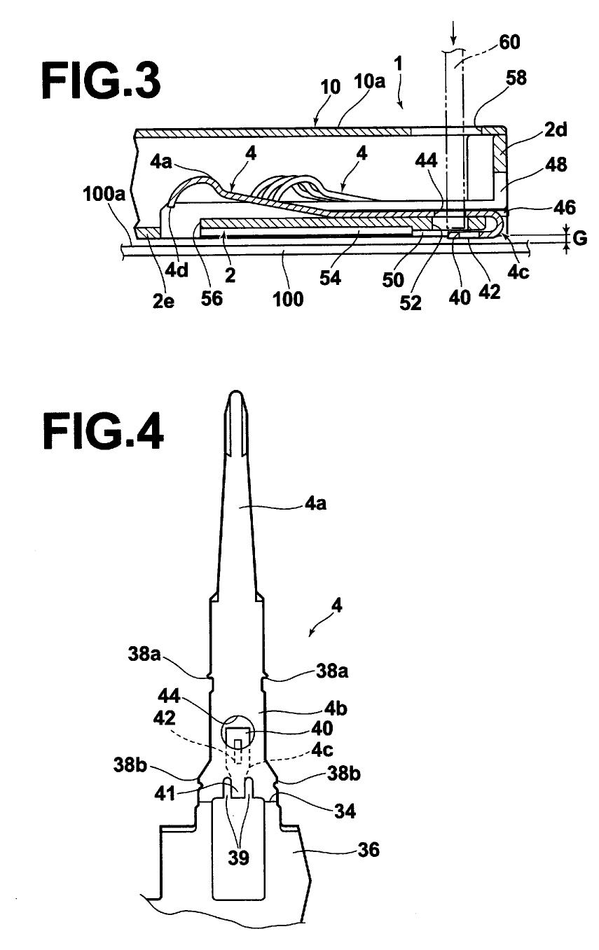

Next, the description will be directed to the shell 10. It is formed of a single metal plate through punching and folding, and comprises a principal surface 10a (FIG. 1B) that covers the upper side of the housing 2, first and second shell side walls 10b, 10c folded over the outer sides of the first and second card guides 2b, 2c, respectively. Protruding rectangular attachment pieces 22 (FIG. 2A) are provided at places adjacent to the front end of the first and second card guides 2b, 2c, and are folded to the under surfaces of the first and second card guides 2b, 2c. This prevents the shell 10 from moving upward from the housing 2. Each attachment piece 22 comprises a rectangular opening 22a in the center and is soldered to a circuit board (substrate) 100 (FIG. 3). The principal surface 10a of the shell 10 that is attached to the housing 2, and housing 2 define a card receiving section 5.

As illustrated in FIGS. 2B, 2C, first and second notches 24a, 24b open to the rear side are provided on the first and second shell side walls 10b, 10c respectively. In the mean time, first and second protrusions 26a, 26b, corresponding to each of the first and second notches 24a, 24b, respectively, are provided on the side surfaces of the card guides 2b, 2c respectively. Engagement of the notches 24a, 24b with the first and second protrusions 26a, 26b prevents the shell 10 from moving upward and backward of the housing 2. The shell 10 comprises, at the rear end portion of the principal surface 10a, first, second, and third lock tongues 28a, 28b, 28c, respectively, which are free at the rear end. The first, second, and third lock tongues 28a, 28b, 28c each comprise a rectangular lock hole, specifically, first, second, and third lock holes 30a, 30b, 30c, respectively. Further, first, second, and third projecting bars 32a, 32b, 32c, corresponding to the lock holes 30a, 30b, 30c, respectively, are provided at the body rear wall 2d of the housing 2. The engagement of the first, second, and third lock holes 30a, 30b, 30c with the first, second, and third projecting bars 32a, 32b, 32c, respectively, prevents the shell 10 from moving the front side of the housing 2.

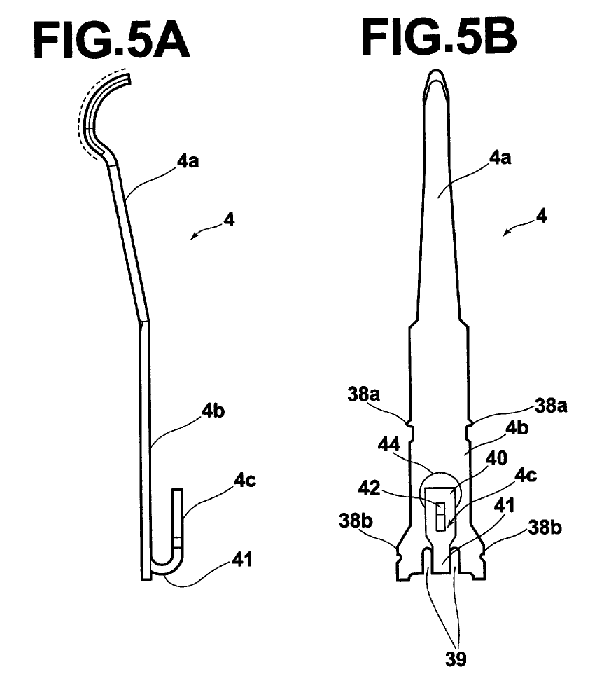

Next, description will be directed to the contact 4 and attachment thereof to the housing 2 with reference also to FIGS. 3 to 5B. First, the contact 4 will be described with reference to FIGS. 4 to 5B. The contact 4 comprises a narrow width contact segment 4a, a wide width retention section 4b, and a tine 4c folded back in a U-shape from the retention section 4b. A contact notch 34, V-shaped in cross section and extending in the direction orthogonal to the axis line along the longitudinal direction of the contact 4, is formed at the rear end of the contact 4. The contact 4 is connected to the carrier strip 36 via the contact notch 34, and separated therefrom by the contact notch 34.

First and second lock protrusions 38a, 38b, spaced apart from each other, are formed at each side edge of the retention section 4b. When the contact 4 is inserted into a contact insertion groove 46, to be described later, of the housing 2, the first and second lock protrusions 38a, 38b engage with the contact insertion groove 46 and are fixed to the housing 2. The contact segment 4a is narrower in width than the retention section 4b, is biased from the retention section 4b, and has an arc-shaped tip. Two slots 39 open to the rear side, are formed at the rear end of the contact 4. A narrow width connection section 41 of the tine 4c extends in a U-shape between the slots 39, followed by a wide width soldering portion 40, which is parallel to the retention section 4b. The soldering portion 40 comprises a rectangular aperture 42 in the center. The aperture 42, like the rectangular opening 22a of the attachment piece 22, increases the soldering strength by increasing the total circumferential length of the soldering portion, as well as increasing the surface tension of the solder when melted. Further, a hole 44 is provided at a position of the retention section 4b right above the soldering portion 40. The hole 44 is a passage hole for a jig 60 (FIG. 3) for allowing access to the soldering portion 40 of the tine 4c.

Next, the description will be directed to the state in which the contact 4 is attached to the housing 2 with reference to FIGS. 1A to 3 again. As illustrated in FIG. 3, the housing 2 comprises a contact insertion groove 46 extending forward along the bottom surface 2e from the rear wall 2d. The contact insertion groove 46 has a width which allows the retention section 4b of the contact 4 to be engaged therewith. Further, a contact insertion opening 48 is provided on the body rear wall 2d to allow the contact 4 to be inserted through the body rear wall 2d. The housing 2 comprises a rectangular depression 50 for accommodating the soldering portion 40 of the tine 4c, and a rectangular channel 52 vertically running through the housing 2 is provided at a position corresponding to the soldering portion 40 placed in the depression 50. The channel 52 of the housing 2 is also connected with the hole 44 of the contact 4.

The housing bottom surface 2e of the housing 2 comprises a V-groove 54, V-shaped in cross-section and extending forward from the depression 50 along the card insertion-ejection directions. The V-groove 54 is provided for reducing thermal stress when the connector 4 is mounted, and formed to the tip of the contact segment 4d and an escape hole 56. The escape hole 56 runs upward through the housing 2 from the housing bottom surface 2e. The escape hole 56 is provided for the tip 4d of the contact segment 4 not to interfere with the housing 2 by bending toward the housing 2 when a card is inserted. The principal surface 10a of the shell 10 comprises a principal surface opening 58 formed aligned with the tine 4c, rectangular channel 52, and hole 44. When the contact 4 is attached to the housing 2, the tine 4c is located inside of the body rear wall 2d, as illustrated in FIG. 3. In other words, the tine 4c remains inside of the outer contour line or footprint of the housing 2 as projected onto the substrate 100 from above the housing. This is clearly illustrated in FIGS. 1B and 2A.

The description will now be directed to a method for correcting the coplanarity of the tines 4c of the contacts 4 structured in the manner as described above. A situation requiring correction of the position of the tine 4c, i.e., the height of the tine 4c from the substrate 100 means a case in which the housing 2 has deformed after forming, and a gap G which is greater than a predetermined value has developed, as illustrated in FIG. 3. The gap G may be detected, for example, by monitoring the connector 1 from the rear side by a camera, and determining variations in the gap G on the image. When a correction is performed, a stick-like jig 60 is inserted from the principal surface opening 58 of the shell 10 to the tine 4c through the hole 44 of the contact 4 and rectangular channel 52 of the housing 2, and the soldering portion 40 is pressed downward, i.e., toward the substrate 100 by the jig 60. This forces the soldering portion 40 to be displaced downward and the gap G is thereby situated within a predetermined range. Generally, the jig 60 has a bottom dead center set thereto to limit the traveling (moving distance) of the jig to a predetermined value and the jig 60 is attached to a machine. The correction of the tine 4c is completed by a single pressing operation of the jig 60. Thereafter, the appropriately positioned soldering portion 40 is soldered to the substrate 100.

In the present embodiment, the rectangular channel 52 of the housing 2 and hole 44 of the contact 4 for inserting the jig 60 have rectangular and circular shapes respectively, but they may alternatively have a polygonal shape, oval shape, or the like. Further, the rectangular channel 52 may have a notch shape, other than an opening with closed perimeter formed in the housing 2.

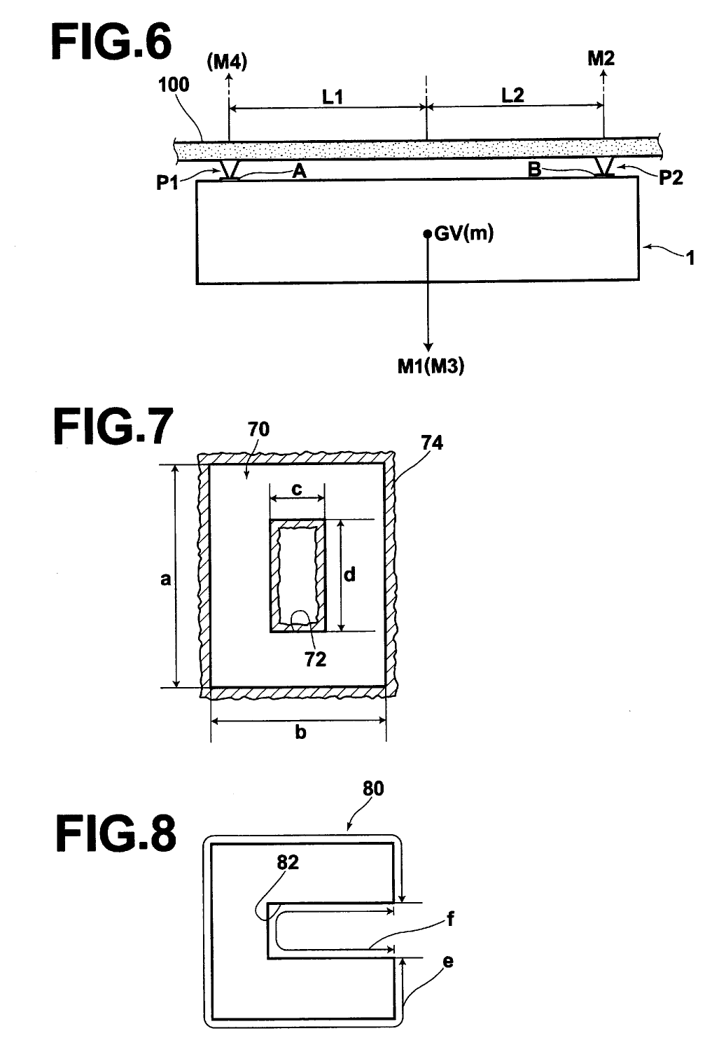

Next, the attachment of the connector 1 to the substrate 100 will be described with reference to FIG. 6. In the second reflow, the solder of a first soldering interface P1 and a second soldering interface P2 is generally melted. The first and second soldering interfaces P1, P2 are generally set at least at two places offset from the center of gravity GV along the longitudinal direction. The rotational moment (moment) generated by the first and second soldering interfaces P1, P2 is as follows.

When the distances from the center of gravity GV of the connector 1 to the first and second soldering interfaces P1, P2 along the longitudinal direction of the substrate are assumed to be L1, L2 respectively, and the weight of the center of gravity GV of the connector 1 is assumed to be m, a first downward moment M1 around the first soldering interface P1, clockwise (downward) in FIG. 6, is expressed as L1×m. The first downward moment M1 acts as a force that pulls downward away from the substrate 100 (tending to pull the connector 1 away from the substrate 100) against the surface tension of the melted solder of the second soldering interface P2. In the mean time, the first upward moment M2 produced by the surface tension having a direction (upward) which is opposite to the first downward moment M1 at the second soldering interfaces P2 is expressed as (L1+L2)Bk. Where, B is the total soldering path length of the soldering portion, and k is a coefficient (empirical value).

The description will now be directed to the total soldering path length with reference to FIG. 7. FIG. 7 is a drawing schematically illustrating a rectangular soldering portion 70 as a specific shape of the soldering interfaces P1, P2 with a passageway 72 in the center. The rectangular soldering portion 70 corresponds to the soldering portion 40 of the attachment piece 22 and contact 4, and the passageway 72 corresponds to the rectangular opening 22a of the attachment piece 22 and the rectangular aperture 42 of the soldering portion 40. In FIG. 7, a solder fillet 74 indicated by slashes is formed at the outer perimeter of the soldering portion 70, and inner perimeter thereof, i.e., inner perimeter of the passageway 72. The total length of the outer perimeter is the sum of each side, i.e., calculated as (a+b)×2, and the total length of the inner perimeter is calculated (c+d)×2, so that the total soldering path length B is calculated as (a+b+c+d)×2. In this case, the first upward moment M2, which is a force that retains the connector 1 produced by the surface tension, is calculated as (L1+L2)Bk. Here, note that the value of the coefficient k is 0.028. The condition required to prevent the connector 1 from falling from the substrates 100 is M1≦M2. That is, the following formula will hold.

M1≦M2

M1=L1×m, M2=(L1+L2)×Bk

L1×m≦(L1+L2)×Bk

B≧(L1×m)/(L1+L2)k (Formula 1)

(where: L1 is the length from the center of gravity to the first soldering interface along the substrate (mm); L2 is the length from the center of gravity to the second soldering interface along the substrate (mm); m is the weight of a surface mount electrical component (g); k is the coefficient (0.028); and B is the total soldering path length of the second soldering interface(mm)).

That is, in the present embodiment, if, for example, the soldering portion 40 of the tine 4c is assumed to correspond to the second soldering interface P2, the rectangular aperture 42 of the soldering portion 40 corresponds to the passageway 72 of the rectangular soldering portion 70. Accordingly, here, if the total soldering path length of the soldering portion 40 of the tine 4c is determined to satisfy B≧(L1×m)/(L1+L2)k, the connector 1 is prevented from falling off the substrate 100 at the second soldering interface P2 or the tine 4c. In actuality, the connector 1 comprises a plurality of contacts 4, and hence, tines 4c located at corresponding positions in the longitudinal direction. Therefore, the total sum B is calculated in consideration of the number of contacts 4.

In the mean time, the solder in the first soldering interface P1 would also be melted, so that it is also necessary to take into account the moment with respect to the second soldering interface P2. In this case, a downward second downward moment M3 caused by gravity at the center of gravity GV of the connector 1 is calculated as L2×m. Assuming that the total soldering path length of the first soldering interface P1 is A, a moment of the opposite direction (upward) M4 caused by the surface tension of the first solder interface P1 is calculated as (L1+L2)×Ak. The condition required to prevent the connector 1 from falling from the substrate 100 is M3≦M4. That is, the following formula will hold.

M3≦M4

M3=L2×m, M4=(L1+L2)×Ak

L2×m≦(L1+L2)×Ak

A≦(L2×m)/(L1+L2)k (Formula 2)

(where, L1 is the length from the center of gravity to the first soldering interface along the substrate (mm); L2 is the length from the center of gravity to the second soldering interface along the substrate (mm); m is the weight of a surface mount electrical component (g); k is the coefficient (in this embodiment, 0.028); and A is the total soldering path length of the first soldering interface (mm)).

In the present embodiment, the first solder interface P1 may be the attachment piece 22 located opposite to the tine 4c across the center of gravity GV. Thus, in this case, the passageway 72 of the soldering portion 70 corresponds to the rectangular opening 22a of the attachment piece 22. Further, the connector 1 comprises a pair of attachment pieces 22 located at corresponding positions in the left/right direction, so that the total sum A is calculated in consideration of the number of attachment pieces 22. If, for example, the soldering portions 70 are not located in left/right symmetrical positions, as the attachment pieces 22, i.e., displaced in the longitudinal direction, the total sum may be calculated for each of them separately.

In actuality, in order to reliably prevent the connector 1 from falling off the substrate 100, it is necessary that both of Formulae 1 and 2 (described above) be satisfied.

So far, an exemplary embodiment of the present invention has been described, but the present invention is not limited to this, and it will be obvious to those skilled in the art that various changes and modifications may be made without departing from the scope of the invention. For example, first and second soldering interfaces P1, P2 may be deemed as the tine 4c and attachment piece 22, respectively, or conversely, as the attachment piece 22 and tine 4c, respectively. Further, the shape of the soldering portion is not necessarily a shape having an opening with closed perimeter, and any shape may be employed as long as it increases the total soldering path length. For example, FIG. 8 illustrates a soldering portion 80 having another shape, in this embodiment a C-shape. The soldering portion 80 illustrated in FIG. 8 has a notch 82, which may be employed as a shape of the soldering portion 80. In this case, the total soldering path length is the sum of the outer perimeter e and inner perimeter f. Of course, a circular or oval hole may alternatively be used instead of a notch.

Further, it will be appreciated that the first and second soldering interfaces may be the attachment piece and tine of the electrical contact, respectively, or vice versa.

1-2. (canceled)

3. A surface mount electrical component, comprising:
a center of gravity;
a first soldering interface longitudinally offset from the center of gravity and having a first soldering interface total solder path length of sufficient length such that a first melted solder fillet substantially disposed along the first soldering interface total solder path length produces a first upward moment greater than a first downward moment produced by the weight of the surface mount electrical component about the first soldering interface;
a second soldering interface longitudinally offset from the center of gravity in a direction opposite that of the first soldering interface so that the center of gravity is longitudinally between the second soldering interface and the first soldering interface, the second soldering interface comprising a second soldering interface total solder path length such that a surface tension produced by a second melted solder fillet substantially disposed along the second soldering interface total solder path length produces a second upward moment greater than a second downward moment produced by the weight of the surface mount electrical component about the second soldering interface.

4. The surface mount electrical component according to claim 3, wherein the length of the first soldering interface total solder path length and the length of the second soldering interface total solder path length satisfy the following formulae:
M1=L1×m, M2=(L1+L2)×Bk;
L1×m≦(L1+L2)×Bk;
B≧(L1×m)/(L1+L2)k;
M3=L2×m, M4=(L1+L2)×Ak;
L2×m≦(L1+L2)×Ak;
A≧(L2×m)/(L1+L2)k;
wherein L1 is the longitudinal distance from the center of gravity to the first soldering interface, L2 is the longitudinal distance from the center of gravity to the second soldering interface, m is a weight of the surface mount electrical component, k is a coefficient, A is the total solder path length of the first soldering interface, and B is the total solder path length of the second soldering interface.

5. The surface mount electrical component according to claim 3, wherein at least one of the first soldering interface and the second soldering interface comprises a substantially rectangular soldering portion.

6. The surface mount electrical component according to claim 5, further comprising an aperture.

7. The surface mount electrical component according to claim 6, wherein the aperture is substantially rectangular in shape.

8. The surface mount electrical component according to claim 7, wherein the soldering portion and the aperture are configured to receive melted solder along substantially the entire perimeters of the soldering portion and the aperture.

9. The surface mount electrical component according to claim 3, further comprising a soldering portion configured for association with a soldering portion of a contact.

10. The surface mount electrical component according to claim 9, wherein the soldering portion of the surface mount electrical component is shaped similar to the shape of the soldering portion of the contact.

11. The surface mount electrical component according to claim 3, further comprising an aperture configured for association with an aperture of a contact.

12. The surface mount electrical component according to claim 11, wherein the aperture of the surface mount electrical component is shaped similar to the shape of the aperture of the contact.

13. The surface mount electrical component according to claim 3, wherein at least one of the first soldering interface and the second soldering interface comprises a soldering portion having a notch.

14. The surface mount electrical component according to claim 13, wherein the soldering portion comprises an inner perimeter and an outer perimeter.

15. The surface mount electrical component according to claim 13, wherein the soldering portion is substantially C-shaped.

16. A method of attaching a surface mount electrical component, comprising the steps of:
joining a first soldering interface to the substrate at a location longitudinally offset from a center of gravity of the surface mount electrical component by applying a first solder fillet along a first soldering interface total solder path;
joining a second soldering interface to the substrate at a location longitudinally offset from the center of gravity of the surface mount electrical component by applying a second solder fillet along a second soldering interface total solder path;
wherein when the first solder fillet and second solder fillet are melted and the surface mount electrical component underneath the substrate, surface tension of the first solder fillet and second solder fillet prevent the surface mount electrical component from falling from the substrate.

17. The method according to claim 16, wherein the center of gravity is located longitudinally between the first soldering interface and the second soldering interface.

18. The method according to claim 16, wherein the first solder fillet and second solder fillet are applied while the surface mount electrical component is above the substrate.

19. The method according to claim 16, wherein the first solder fillet and second solder fillet are located equal distances longitudinally from the center of gravity.

20. The method according to claim 16, wherein the surface tension generated by the first solder fillet produces a first upward moment greater than a first downward moment produced by the weight of the surface mount electrical component about the first soldering interface and wherein the surface tension generated by the second solder fillet produces a second upward moment greater than a second downward moment produced by the weight of the surface mount electrical component about the second soldering interface.

21. The method according to claim 20, wherein the length of the first soldering interface total solder path length and the length of the second soldering interface total solder path length satisfy the following formulae:
M1=L1×m, M2=(L1+L2)×Bk;
L1×m≦(L1+L2)×Bk;
B≧(L1×m)/(L1+L2)k;
M3=L2×m, M4=(L1+L2)×Ak;
L2×m≦(L1+L2)×Ak;
A≧(L2×m)/(L1+L2)k;
wherein L1 is the longitudinal distance from the center of gravity to the first soldering interface, L2 is the longitudinal distance from the center of gravity to the second soldering interface, m is a weight of the surface mount electrical component, k is a coefficient, A is the total solder path length of the first soldering interface, and B is the total solder path length of the second soldering interface.

22. The method according to claim 16, wherein at least one of the first soldering interface and the second soldering interface comprises a substantially rectangular soldering portion.
